(19) United States
(12) Patent Application Publication
(10) Pub. No.: US 2002/0117102 A1
(43) Pub. Date: Aug. 29, 2002

(54) Iron nitride thin film and methods for production thereof

(76) Inventors: Tadashi Takahashi, Hamamatsu-shi (JP); Naoyuki Takahashi, Hamamatsu-shi (JP); Takato Nakamura, Hamamatsu-shi (JP)

Correspondence Address: MYERS BIGEL SIBLEY & SAJOVEC, PO BOX 37428, RALEIGH, NC, 27627, US

(21) Appl. No.: 10/025,681

(22) Filed: Dec. 19, 2001

(30) Foreign Application Priority Data
Dec. 27, 2000 (JP) 2000-396679

(51) Int. Cl. C30B 25/00; C30B 23/00; C30B 28/14; C30B 28/12

(52) U.S. Cl. 117/84

(57) ABSTRACT

The present invention provides a method for the preparation of an iron nitride thin film by which an iron nitride thin film having a high growth rate can be epitaxially grown under atmospheric pressure without using any expensive vacuum system or raw materials, and an iron nitride thin film prepared by this method. This method for the preparation of an iron nitride thin film comprises the steps of vaporizing an iron halide used as a raw material 51 for the preparation of a thin film and reacting the resulting iron halide gas with a nitrogen source gas 7 containing nitrogen to produce an iron nitride gas; and preparing an epitaxial film of iron nitride 63 on a substrate 61 by allowing the iron halide gas to become adsorbed on the substrate 61 under atmospheric pressure and grow epitaxially thereon.

### BACKGROUND OF THE INVENTION

1. Field of the Invention

This invention relates to iron nitride thin films which are extensively used in the electronics industry, particularly in the manufacture of magnetic devices such as magnetic heads, and methods for production thereof.

2. Description of the Related Art

Metallic nitride is one of the interesting materials because its electrical, magnetic, optical and chemical properties vary with its preparation method, their preparation conditions, and the like. Among others, iron nitride having a high saturation flux density at room temperature is being extensively developed by various preparation technique of its thin film while aiming at its application to magnetic devices. Examples of actively investigated techniques for the preparation of an iron nitride thin film by using plasma CVD (Japanese Patent Provisional Publication No. 63-31536), ion plating (J. of Applied Physics, JP, Vol. 23, p. 1576, 1984) and molecular-beam epitaxy (Japanese Patent Provisional Publication No. 2-30700).

However, these methods are disadvantageous in that they require an expensive vacuum system and raw materials and have a slow growth rate. Consequently, they are unsuitable for industrial production under atmospheric pressure. The epitaxial growth of an iron nitride thin film under atmospheric pressure has not been reported yet.

Moreover, Japanese Patent Provisional Publication No. 5-112869 has proposed a method for the preparation of an iron nitride thin film which comprises heating a substrate to 100-400° C. in a gaseous atmosphere of tricarbonyliron being an iron complex, and thermally decomposing the resulting gas of the aforesaid complex at the surface of the substrate. However, owing to the use of a special gas, this method is disadvantageous in that it involves a high material cost and has a slow growth rate (100 Å/min).

An object of the present invention is to solve the above-described problems by providing a method for the preparation of an iron nitride thin film by which an iron nitride thin film having a high growth rate can be epitaxially grown under atmospheric pressure without using any expensive vacuum system or raw materials, and an iron nitride thin film prepared by this method.

### SUMMARY OF THE INVENTION

In order to accomplish the above object, the present invention provides a method for the preparation of an iron nitride thin film which comprises the steps of vaporizing an iron halide and reacting the resulting iron halide gas with a nitrogen source gas containing nitrogen to produce an iron nitride gas; and preparing an epitaxial film of iron nitride on a substrate by allowing the iron nitride gas to become adsorbed on the substrate under atmospheric pressure and grow epitaxially thereon.

Since the film-growth rate of the above-described method is 10 or more times as high as those of conventional methods, high productivity can be achieved. Moreover, a thin film having excellent crystallinity and magnetic properties can be prepared by use of an inexpensive apparatus. The aforesaid nitrogen source gas may be any gas that serves as a nitrogen source for iron nitride. For example, ammonia gas, hydrazine, dimethylhydrazine and the like may be used, and diluted gases may also be used.

In another embodiment of the method for the preparation of an iron nitride thin film in accordance with the present invention, a substrate having a surface coated with an iron-containing buffer layer is used and an epitaxial film of iron nitride is prepared on the buffer layer.

This method is useful when there is a considerable lattice mismatch between the epitaxial film of iron nitride and the substrate. Even in such a case, this method can mitigate the lattice mismatch and thereby achieve an improvement in crystallinity. Moreover, the use of a buffer layer makes it possible to prepare a film on a wide variety of substrates including oxides, semiconductors and metallic materials.

In still another embodiment of the method for the preparation of an iron nitride thin film in accordance with the present invention, the aforesaid iron nitride comprises Fe₄N and this method is useful in preparing a thin film of Fe₄N on a substrate.

This method makes it possible to prepare an epitaxial film of Fe₄N which has excellent magnetic properties and has not been known in the prior art.

In a further embodiment of the method for the preparation of an iron nitride thin film in accordance with the present invention, at least one compound selected from the group consisting of FeCl₃, FeI₃, FeBr₃, FeCl, FeI₂ and FeBr₂ is used as the aforesaid iron halide.

The present invention also provides a method for the preparation of an iron nitride thin film which comprises the steps of vaporizing an iron halide under atmospheric pressure and conveying the resulting iron halide gas to a substrate with the aid of a carrier gas; conveying a gas serving as a nitrogen source with the aid of a carrier gas; and preparing an epitaxial film of iron nitride on the substrate by reacting both gases.

In this method, a substrate having a surface coated with an iron-containing buffer layer may be used and an epitaxial film of iron nitride may be prepared on the buffer layer.

Similarly to the previously described embodiment, this method is useful when there is a considerable lattice mismatch between the epitaxial film of iron nitride and the substrate. Even in such a case, this method can mitigate the lattice mismatch and thereby achieve an improvement in crystallinity. Moreover, the use of a buffer layer makes it possible to prepare a film on a wide variety of substrates including oxides, semiconductors and metallic materials.

The present invention also provides an iron nitride thin film prepared by any of the above-described methods for the preparation of an iron nitride thin film.

According to the present invention, an iron nitride thin film having good crystallinity can be rapidly prepared at a low cost.

Thus, the present invention makes it possible to prepare an epitaxial film of iron nitride to be prepared under atmospheric pressure and at a low cost. Even when there is a considerable crystallographic mismatch between this epitaxial film and the substrate, an epitaxial film having good crystallinity may be prepared by coating the substrate with a buffer layer and allowing an epitaxial film to grow on this buffer layer.

### BRIEF DESCRIPTION OF THE DRAWINGS

FIG. 1(a) is a schematic view of a film-preparing apparatus for use in an embodiment of the present invention, and

FIG. 1(b) is a graph showing the internal temperature of the film-preparing apparatus of FIG. 1(a);

FIG. 2 is a graph showing the results of X-ray diffraction analysis of a thin film obtained in an example of the present invention;

FIG. 3 is a graph showing the magnetization curve at room temperature of the Fe₄N thin film obtained in the example of the present invention; and

FIG. 4 is a plot of the growth rate of the Fe₄N thin film against the feed rate of FeCl₃ as observed in the example of the present invention.

### DETAILED DESCRIPTION OF PREFERRED EMBODIMENTS

An embodiment of the present invention will be more specifically described hereinbelow.

[Method For the Preparation of an Iron Nitride Thin Film]

First of all, a gas of an iron halide is produced by vaporizing an iron halide used as a raw material for the preparation of a thin film. This gas is produced by heating the iron halide to vaporize at least a portion of the iron halide, and conveyed to a substrate with the aid of a carrier gas. As this carrier gas, there may be used an inert gas such as argon or helium. However, nitrogen gas is preferred because of its low cost. The feed rate of the iron halide gas can be controlled by regulating the heating temperature and the flow rate of the carrier gas.

Then, ammonia (NH₃) gas serving as a nitrogen source is fed to the substrate. Similarly to the carrier gas used to convey the iron halide gas, an inert gas such as argon or helium may also be used for the purpose of feeding ammonia gas. However, nitrogen gas is preferred because of its low cost.

These iron halide gas and ammonia gas are reacted together to prepare an iron nitride gas. As the iron nitride, there may be prepared FeN, Fe₃N, Fe₄N and the like.

The aforesaid iron nitride gas is adsorbed to the substrate and allowed to grow epitaxially thereon. Thus, the iron nitride is progressively deposited on the substrate to prepare an epitaxial film of iron nitride.

[Substrate]

The material of the substrate is preferably such that it has the same crystal structure as the iron nitride being prepared into a film and, moreover, it has a lattice constant close to that of the iron nitride. Useful materials of the substrate include, for example, oxide materials such as MgO(100), MgO(200), CeO₂, sapphire, SrTiO₃ and NdGaO₃; semiconductor materials such as Si, GaAs, GaP, AlGaAs, GaN, InN and AlN; and metallic materials such as Fe, Ni, Cu, Zn, Mn, Ag and Al. Moreover, within the film-preparing apparatus, the substrate is preferably heated to and maintained at a constant temperature of 450 to 700° C. The substrate may be disposed so as to be parallel to the flow of the raw material gas or perpendicular thereto. Furthermore, the substrate may be inclined so as to prepare an angle with the flow of the raw material gas.

Moreover, an epitaxial film having good crystallinity may be prepared by preparing a buffer layer on the substrate in order to mitigate the mismatch in lattice constant, and growing an iron nitride thin film on this buffer layer. As the buffer layer, there may be used Fe, Fe₄N, Fe₃N, GaN, CeO₂, ZnO or the like. In such a case, the X-ray half width, which serves as a measure of crystallinity, is markedly improved from 10 minutes to 1 minute.

[Raw Material For the Preparation of a Thin Film]

An iron halide may be used as a raw material for the preparation of an iron nitride thin film. Among others, a ferric halide such as FeCl₃, FeI₃ or FeBr₃ may preferably be used as the iron halide. Moreover, this iron halide need not have such a high purity (e.g., 3N or above) as is required by conventional processes using a vacuum system, and a purity of the order of 99.5% will suffice. Consequently, the method of the present invention involves only a low material cost.

An apparatus for preparing an iron nitride thin film according to the method of the present invention is described below with reference to the accompanying drawings.

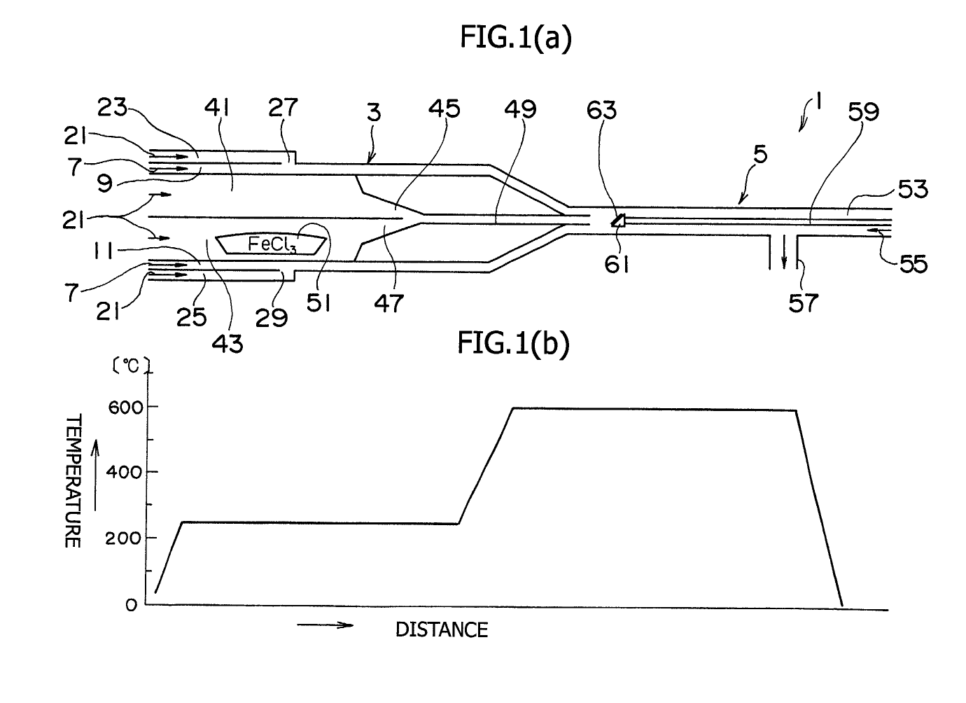

FIG. 1(a) is a schematic view of a film-preparing apparatus 1 for use in an embodiment of the present invention. The left half of this film-preparing apparatus 1 is a raw material feeding section 3, and the right half thereof is a growth section 5.

In raw material feeding section 3, nitrogen source gas feed passages 9,11 for feeding a nitrogen source gas 7 (e.g., ammonia gas) are disposed on the upper and lower sides thereof. Moreover, feed passages 23,25 for a carrier gas (e.g., nitrogen gas) 21 are provided in parallel with these nitrogen source gas feed passages 9,11. The downstream ends 27,29 of these carrier gas feed passages 23,25 communicate with an intermediate part of nitrogen source gas feed passages 9,11. The upper nitrogen source gas feed passage 9 and the lower nitrogen source gas feed passage 11 are combined together at their downstream ends, and extend to growth section 5.

Moreover, other upper and lower carrier gas feed passages 41,43 are disposed between the upper and lower nitrogen source gas feed passages 9,11. Similarly, a carrier gas 21 (e.g., nitrogen gas) is also fed to these carrier gas feed passages 41,43. These carrier gas feed passages 41,43 are combined together at their downstream ends 45,47 to prepare a single carrier gas feed passage 49, which extends to growth section 5. A raw material 51 for the preparation of a thin film, which serves as an iron source, is placed in the aforesaid lower carrier gas feed passage 43. The aforesaid carrier gas 21 functions to convey the nitrogen source gas and the vaporized gas of iron source material 51 and also to dilute these raw material gases and thereby control the partial pressures of the raw material gases. Thus, the feed rates of the raw materials, which are important conditions for film preparation, can be closely controlled. The vertical and horizontal arrangement of components in the film-preparing apparatus 1 of FIG. 1(a) is not critical. What is essential is that the raw material gases are mixed and reacted together on the substrate.

As described above, two nitrogen source gas feed passages 9,11 and two carrier gas feed passages 41,43 are provided. Consequently, nitrogen source gas 7 and the gas of iron source material 51 can be fed to growth section 5 in large amounts to enhance the growth rate of an iron nitride thin film.

Furthermore, the aforesaid growth section 5 is constructed so that a carrier gas 55 (e.g., nitrogen gas) may be fed through a carrier gas feed passage 53 disposed at the right-hand end and the gas within film-preparing apparatus 1 may be discharged through an exhaust port 57 opening on the lower side. A substrate 61 is attached to the tip of a rod 59. Carrier gas 55 introduced through the aforesaid carrier gas feed passage 53 functions to stagnate the flow of gas within growth section 5 for purposes of reaction and to direct the gas to exhaust port 57. The total pressure within this film-preparing apparatus 1 is kept nearly equal to atmospheric pressure.

FIG. 1(b) is a graph showing the temperature within the film-preparing apparatus 1 of FIG. 1(a). This temperature is shown as a function of the horizontal position in film-preparing apparatus 1. The temperature of the aforesaid raw material feeding section 3 is preferably maintained in the range of about 150 to 350° C., and the temperature of the aforesaid growth section 5 is preferably maintained in the range of about 450 to 700° C.

The time required for film preparation is preferably in the range of 10 to 60 minutes.

### EXAMPLE

Now, the present invention is more specifically explained with reference to the following example.

Using a film-preparing apparatus 1 as illustrated in FIG. 1(a), an epitaxial film of Fe₄N was prepared on an MgO(100) substrate 61 under the conditions shown in Table 1 below. This film-preparing apparatus 1 was a horizontal type quartz reactor and had a horizontal temperature profile as shown in FIG. 1(b). Raw material feeding section 3 illustrated on the left-hand side of the figure was maintained at a temperature of 250° C., and growth section 5 illustrated on the right-hand side of the figure was maintained at a temperature of 600° C. The unit “sccm” shown in Table 1 is an abbreviation for “standard cubic centimeters per minute”.

TABLE 1

| Conditions for the preparation of an | | |
|---|---|---|
| epitaxial film of Fe₄N | | |
| Feed rate of FeCl₃ feed gas (N₂ gas; | 25 | sccm |
| numeral 21 in FIG. 1) | | |
| Feed rate of diluent gas for FeCl₃ (N₂ gas; | 365 | sccm |
| numeral 21 in FIG. 1) | | |
| Feed rate of NH₃ feed gas (NH₃ gas; numeral | 10 | sccm |
| 7 in FIG. 1) | | |
| Feed rate of diluent gas for NH₃ (N₂ gas; | 90 | sccm |
| numeral 21 in FIG. 1) | | |
| Feed rate of NH₃ feed gas (NH₃ gas; numeral | 10 | sccm |
| 7 in FIG. 1) | | |
| Feed rate of diluent gas for NH₃ (N₂ gas; | 90 | sccm |
| numeral 21 in FIG. 1) | | |
| Feed rate of diluent gas for NH₃ (N₂ gas; | 250 | sccm |
| numeral 55 in FIG. 1) | | |
| Carrier gas | N₂ gas | |
| Temperature of FeCl₃ | 250° C. | |
| Temperature of substrate | 600° C. | |
| Substrate | MgO (100) | |
| Total pressure | 1 | atm |
| Growth time | 1 | h |

In the raw material feeding section 3 of the above-described film-preparing apparatus 1, FeCl₃ used as iron source material 51 was placed in a source boat (not shown). Since raw material feeding section 3 was maintained at a high temperature of 250° C. as shown in FIG. 1(b), a portion of FeCl₃ was vaporized to produce FeCl₃ gas, which was conveyed to growth section 5 with the aid of nitrogen gas used as carrier gas 21. On the other hand, ammonia gas used as nitrogen source gas 7 was introduced through nitrogen source gas feed passages 9,11 and fed to growth section 5 at a predetermined partial pressure with the aid of nitrogen gas used as carrier gas 21.

Since growth section 5 was maintained at 600° C., FeCl₃ gas and ammonia gas reacted together to produce an iron nitride gas. This gas became adsorbed on a surface of MgO(100) used as substrate 61 and grew epitaxially thereon, resulting in the preparation of an epitaxial film. After this film-preparing process was carried out for 1 hour, an iron nitride thin film 63 having a thickness of 8 μm was obtained.

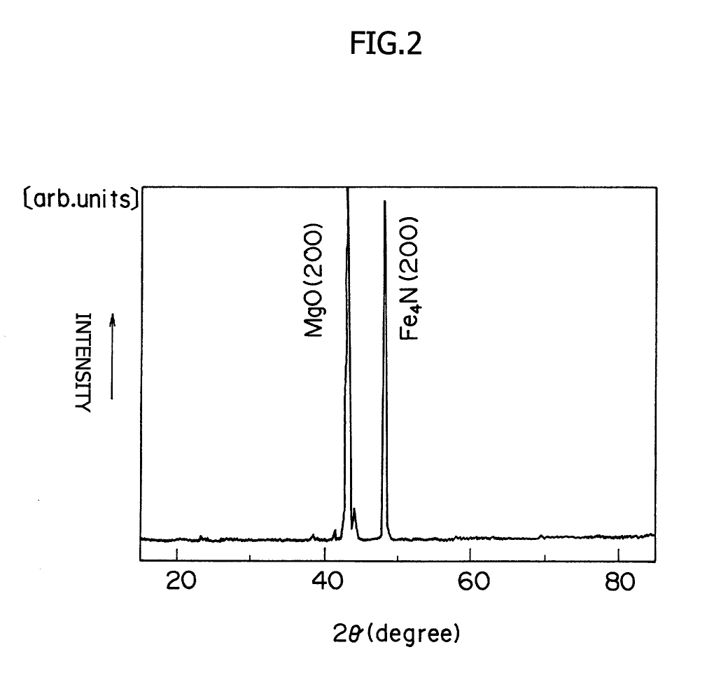

When this thin film 63 was subjected to an X-ray diffraction (XRD) analysis, sharp diffraction peaks for MgO(200) (i.e., substrate 61) and Fe₄N(200) were recognized as shown in FIG. 2. Thus, it has been found that the resulting thin film 63 was an epitaxial film of Fe₄N. No report has been made on the preparation of an epitaxial film of Fe₄N, and its preparation has been made possible for the first time by the present invention.

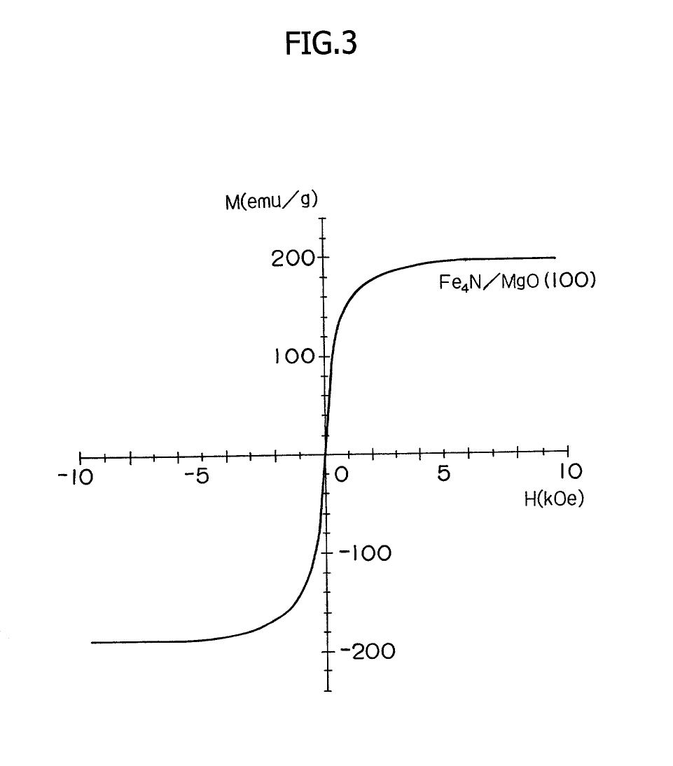

A hysteresis curve constructed by measuring the magnetic characteristics of Fe₄N thin film 63 so prepared is shown in FIG. 3. As shown in FIG. 3, the maximum saturation magnetization of Fe₄N was 182 emu/g and its coercive force was 30 Oe. Since this hysteresis curve exhibits superparamagnetic behavior, Fe₄N thin film 63 is found to be a soft magnetic material useful, for example, in magnetic heads.

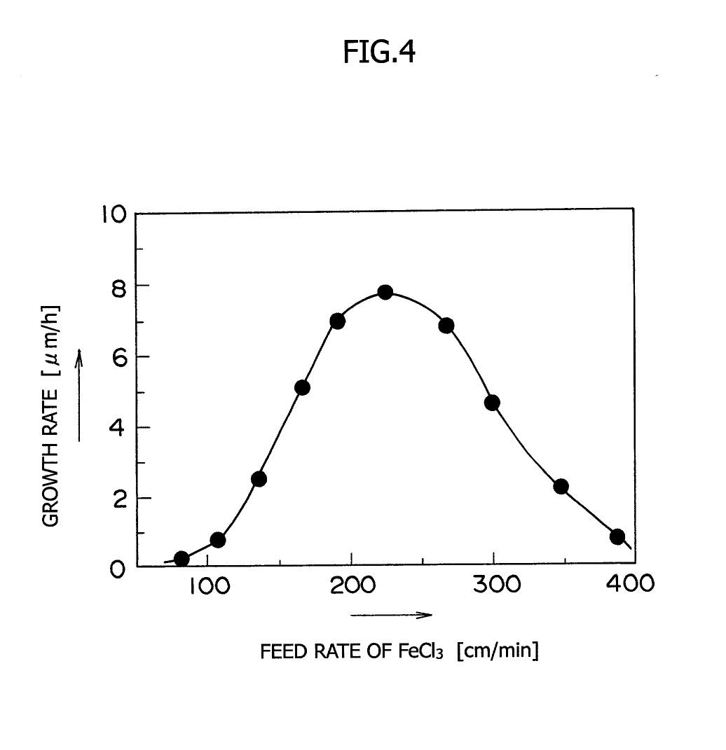

Moreover, the influence of the feed rate (linear velocity) of FeCl₃ on the growth rate of the Fe₄N thin film is shown in FIG. 4. It can be seen from FIG. 4 that, when the feed rate of FeCl₃ went out of the range of 100 to 400 cm/min, the growth rate of Fe₄N thin film 63 was markedly reduced. The maximum value of this growth rate was about 8 μm/h.

1. A method for the preparation of an iron nitride thin film which comprises the step of preparing an epitaxial film of iron nitride on a substrate by reacting a vaporized iron halide with a nitrogen source gas under atmospheric pressure and depositing the resulting iron nitride on the substrate so as to cause epitaxial growth thereof.

2. A method for the preparation of an iron nitride thin film as claimed in claim 1 which further comprises the steps of using a substrate having a surface coated with an iron-containing buffer layer and preparing an epitaxial film of iron nitride on the buffer layer.

3. A method for the preparation of an iron nitride thin film as claimed in claim 1 or 2 wherein the iron halide is at least one compound selected from the group consisting of FeCl₃, FeI₃, FeBr₃, FeCl, FeI₂ and FeBr₂.

4. A method for the preparation of an iron nitride thin film as claimed in any of claims 1 to 3 wherein the iron nitride contains Fe₄N.

5. A method for the preparation of an iron nitride thin film which comprises the steps of vaporizing an iron halide under atmospheric pressure and directing the resulting iron halide gas to a substrate; and preparing an epitaxial film of iron nitride on the substrate by reacting the iron halide gas with a gas serving as a nitrogen source and depositing the resulting iron nitride on the substrate.

6. A method for the preparation of an iron nitride thin film which comprises the steps of vaporizing an iron halide under atmospheric pressure and conveying the resulting iron halide gas to a substrate with the aid of a carrier gas; conveying a gas serving as a nitrogen source with the aid of a carrier gas; and preparing an epitaxial film of iron nitride on the substrate by reacting both gases.

7. A method for the preparation of an iron nitride thin film as claimed in claim 5 or 6 which further comprises the steps of using a substrate having a surface coated with an iron-containing buffer layer and preparing an epitaxial film of iron nitride on the buffer layer.

8. An iron nitride thin film prepared by a method as claimed in any of claims 1 to 7.
